(19) United States
(12) Patent Application Publication
(10) Pub. No.: US 2025/0364476 A1
(43) Pub. Date: Nov. 27, 2025

(54) SEMICONDUCTOR PACKAGE AND METHOD OF FABRICATING THE SAME

(71) Applicant: Samsung Electronics Co., Ltd., Suwon-si (KR)

(72) Inventor: Eun Su LEE, Suwon-si (KR)

(21) Appl. No.: 19/185,065

(22) Filed: Apr. 21, 2025

(30) Foreign Application Priority Data
May 23, 2024 (KR) 10-2024-0066866

(51) Int. Cl. H01L 23/00; H01L 21/48; H01L 21/56; H01L 23/13; H01L 23/498; H01L 23/538; H01L 25/18; H10B 80/00; H10D 80/30

(52) U.S. Cl. CPC H01L 24/32; H01L 21/4853; H01L 21/565; H01L 23/13; H01L 23/49838; H01L 23/49866; H01L 23/5385; H01L 24/16; H01L 24/26; H01L 24/48; H01L 24/73; H01L 25/18; H10B 80/00; H10D 80/30; H01L 2224/16227; H01L 2224/26175; H01L 2224/3201; H01L 2224/32054; H01L 2224/32058; H01L 2224/32059; H01L 2224/32225; H01L 2224/48147; H01L 2224/48227; H01L 2224/73204; H01L 2225/06506; H01L 2225/0651; H01L 2225/06517; H01L 2225/06524; H01L 2225/06562; H01L 2924/1431

(57) ABSTRACT

A semiconductor package includes a first substrate including a first region and a second region, an underfill dam separating the first substrate into the first region and the second region, wherein the underfill dam surrounds the first region, a first semiconductor chip mounted on the first region, a second semiconductor chip mounted on the second region, a first electrode pad and a second electrode pad disposed on the first region, a bump connecting the first electrode pad to the first semiconductor chip, a first wire connecting the second electrode pad to the second semiconductor chip, and an underfill disposed on the first region and surrounding the bump and an end of the first wire that contacts the second electrode pad.

### CROSS-REFERENCE TO RELATED APPLICATION

This application claims priority from Korean Patent Application No. 10-2024-0066866 filed on May 23, 2024 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a semiconductor package and a method of fabricating the same.

### 2. Description of the Related Art

As the storage capacity of semiconductor chips increases, there is a demand for semiconductor packages containing these chips to become thinner and more lightweight. Additionally, there is a trend toward incorporating semiconductor chips with various functions into semiconductor packages and conducting research to drive these semiconductor chips more rapidly. In response to this trend, studies on package-on-package type semiconductor packages, where an upper semiconductor package is mounted on a lower semiconductor package, are being conducted.

### SUMMARY

Aspects of the present disclosure provide a semiconductor package with improved reliability.

Aspects of the present disclosure also provide a tiled display device capable of

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a semiconductor package includes a first substrate including a first region and a second region, an underfill dam separating the first substrate into the first region and the second region, wherein the underfill dam surrounds the first region, a first semiconductor chip mounted on the first region, a second semiconductor chip mounted on the second region, a first electrode pad and a second electrode pad disposed on the first region, a bump connecting the first electrode pad to the first semiconductor chip, a first wire connecting the second electrode pad to the second semiconductor chip, and an underfill disposed on the first region and surrounding the bump and an end of the first wire that contacts the second electrode pad.

According to an aspect of the present disclosure, a method of fabricating a semiconductor package includes providing a first substrate including a first region and a second region, which are separated by an underfill dam, providing a first electrode pad and a second electrode pad on the first region, mounting a first semiconductor chip on the first region, wherein the first semiconductor chip is connected to the first electrode pad, mounting a second semiconductor chip on the second region, connecting the second semiconductor chip to the second electrode pad with a wire, and applying an underfill into the underfill dam after the connecting of the second semiconductor chip to the second electrode pad with the wire. The underfill surrounds an end of the wire that contacts the second electrode pad.

According to an aspect of the present disclosure, a semiconductor package includes a first substrate including a first region and a second region, an underfill dam separating the first substrate into the first region and the second region, wherein the underfill dam surrounds the first region, an interposer disposed on the first substrate, a third substrate disposed on the interposer, a first semiconductor chip mounted on the first region, a second semiconductor chip mounted on the second region, a third semiconductor chip mounted on the third substrate, a first electrode pad and a second electrode pad disposed on the first region, a package connection pad disposed between the interposer and the third substrate, a bump connecting the first electrode pad to the first semiconductor chip, a wire connecting the second electrode pad to the second semiconductor chip, a plurality of vertical connectors disposed between the first substrate and the interposer, electrically connecting the first substrate to the interposer, and an underfill disposed on the first region and surrounding the bump and an end of the wire that contacts the second electrode pad. The interposer includes a lower surface facing the first substrate, and a cavity disposed at the lower surface of the interposer. The cavity overlaps an uppermost part of the wire. The plurality of vertical connectors include a plurality of core structures and a plurality of solder balls. Each of the plurality of core structures includes a solder layer and a core layer. The solder layer includes at least one of tin (Sn), silver (Ag), and copper (Cu). The core layer includes copper. A region where the plurality of core structures are disposed is closer to the first semiconductor chip than a region where the plurality of solder balls are disposed.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a cross-sectional view of a semiconductor package according to some embodiments of the present disclosure;

FIG. 2 is a top view of a semiconductor package according to some embodiments of the present disclosure;

FIGS. 3 and 4 are cross-sectional views of part B of FIG. 1;

FIG. 5 is a top view of a semiconductor package according to some embodiments of the present disclosure;

FIGS. 6 through 12 are cross-sectional views illustrating a method of fabricating a semiconductor package according to some embodiments of the present disclosure; and

FIGS. 13 through 15 are cross-sectional views of semiconductor packages according to some embodiments of the present disclosure.

### DETAILED DESCRIPTION

Exemplary embodiments of the present disclosure will hereinafter be described in detail with reference to the accompanying drawings. The same reference numerals are used for the same components in the drawings, and redundant descriptions thereof will be omitted.

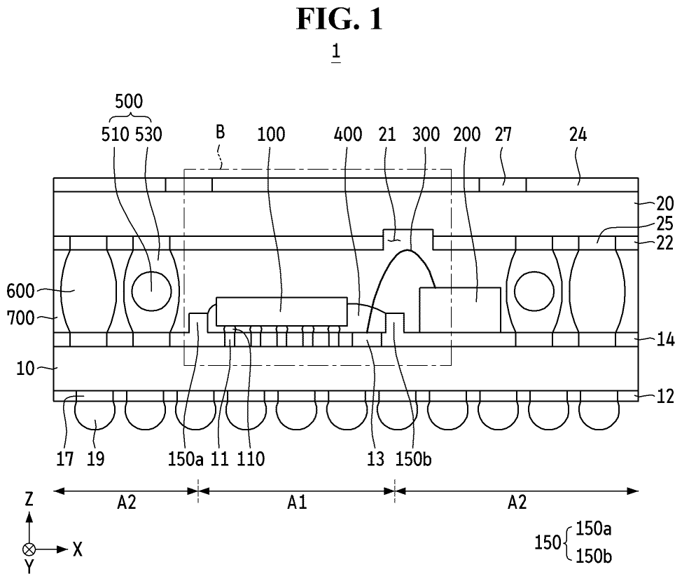

FIG. 1 is a cross-sectional view of a semiconductor package according to some embodiments of the present disclosure.

Referring to FIG. 1, a semiconductor package 1 may include a first substrate 10 and a first semiconductor chip 100, a second semiconductor chip 200, a plurality of vertical connectors 500 and 600, and a second substrate 20, which are disposed on the first substrate 10.

In some embodiments, the first substrate 10 may be a printed circuit board. For example, the first substrate 10 may be a multi-layer printed circuit board, but the present disclosure is not limited thereto.

The first substrate 10 may include a substrate body which includes at least one material selected from phenolic resin, epoxy resin, and polyimide. For example, the first substrate 10 may include at least one material selected from Frame Retardant 4 (FR4), tetrafunctional epoxy, polyphenylene ether, epoxy/polyphenylene oxide, BT (Bismaleimide triazine), Thermount, cyanate ester, polyimide, and liquid crystal polymer, but the present disclosure is not limited thereto.

In some embodiments, the first substrate 10 may further include a first solder resist layer 12 and 14. The first solder resist layer 12 and 14 may include a first upper solder resist layer 14, which exposes a plurality of first upper pads 11 and a first wire pad 13 and covers the upper surface of the first substrate body, and a first lower solder resist layer 12, which exposes a plurality of first lower pads 17 and covers the lower surface of the first substrate body.

A plurality of external connection terminals 19 may be attached to at least some of the first lower pads 17. The external connection terminals 19 may electrically connect the semiconductor package 1 to the outside. For example, the external connection terminals 19 may be solder balls or bumps, but the present disclosure is not limited thereto.

In some embodiments, the first substrate 10 may include an underfill dam 150, which protrudes from the upper surface of the first substrate 10. The underfill dam 150 may separate a first region A1 and a second region A2 of the first substrate 10. The underfill dam 150 may limit the area where an underfill 400 is applied. In some embodiments, the underfill dam 150 may be disposed on an upper surface of the first upper solder resist layer 14 and define an area where the underfill 400 is present. In some embodiments, when viewed in a plan view, the underfill dam 150 may surround the underfill 400.

The first substrate 10 may include a plurality of first substrate pads. The first substrate pads may include the first upper pads 11 and the first wire pad 13, which are disposed on the upper surface of the first substrate 10 (e.g., an upper surface of the first substrate body), and the first lower pads 17, which are disposed on the lower surface of the first substrate 10 (e.g., a lower surface of the first substrate body). Through the first wire pad 13, the second semiconductor chip 200, mounted in the second region A2, may be electrically connected to the first substrate 10.

In some embodiments, the first substrate pads may include copper (Cu). For example, the first substrate pads may be formed of electrolytically-deposited (ED) Cu foil, rolled-annealed (RA) Cu foil, ultrathin Cu foil, sputtered Cu, Cu alloy, etc.

In some embodiments, the underfill dam 150 may include a first sub-dam 150a and a second sub-dam 150b. The second sub-dam 150b may be disposed between the first and second semiconductor chips 100 and 200. In some embodiments, when viewed in a plan view, the underfill dam 150 may surround the underfill 400.

As the first wire pad 13 is disposed between the first semiconductor chip 100 and the second sub-dam 150b, the distance between the first sub-dam 150a and the first semiconductor chip 100 may be smaller than the distance between the second sub-dam 150b and the first semiconductor chip 100.

In some embodiments, the first semiconductor chip 100 may be mounted in the first region A1 of the first substrate 10.

In some embodiments, the first semiconductor chip 100 may be a central processing unit (CPU) chip, a graphics processing unit (GPU) chip, a modem chip, or an application processor (AP) chip.

In some embodiments, the first semiconductor chip 100 may be, for example, a memory semiconductor chip. The memory semiconductor chip may be, for example, a non-volatile memory semiconductor chip such as a flash memory, Phase-change Random Access Memory (PRAM), Magnetoresistive Random Access Memory (MRAM), Ferroelectric Random Access Memory (FeRAM), and Resistive Random Access Memory (RRAM). The flash Memory may be, for example, a NAND flash memory or a V-NAND flash memory. In some embodiments, the first semiconductor chip 100 may be a volatile memory semiconductor chip such as a Dynamic Random Access Memory (DRAM) and a Static Random Access Memory (SRAM).

In some embodiments, a plurality of chip connection members 110 may be interposed between the first semiconductor chip 100 and some of the first upper pads 11 of the first substrate 10. The chip connection members 110 may be, for example, solder balls or bumps, but the present disclosure is not limited thereto. The first semiconductor chip 100 and the first substrate 10 may be electrically connected through the chip connection members 110.

In some embodiments, the second semiconductor chip 200 may be mounted in the second region A2 of the first substrate 10.

In some embodiments, the second semiconductor chip 200 may be, for example, a memory semiconductor chip. The memory semiconductor chip may be, for example, a non-volatile memory semiconductor chip such as a flash memory, PRAM, MRAM, FeRAM, and RRAM. The flash memory may be, for example, a NAND flash memory or a V-NAND flash memory. Alternatively, in some embodiments, the second semiconductor chip 200 may be a volatile memory semiconductor chip such as a DRAM or SRAM.

In some embodiments, the second semiconductor chip 200 may be electrically connected to the first wire pad 13, installed on the first substrate 10, by a wire 300. Consequently, the second semiconductor chip 200 and the first substrate 10 may be electrically connected.

In some embodiments, the underfill 400 may be interposed between the first semiconductor chip 100 and the upper surface of the first substrate 10 (e.g., the first upper solder resist layer 14). The underfill 400 may surround the chip connection members 110 and the end of the wire 300 that contacts the first wire pad 13. In some embodiments, the underfill 400 may fill a space between the upper surface of the first upper solder resist layer 14 and a lower surface of the first semiconductor chip 100 and may at least partially cover a side surface of the first semiconductor chip 100. An end portion of the wire 300 may be buried in the underfill 400.

In some embodiments, the underfill 400 may be formed of an epoxy resin obtained by, for example, a capillary under-fill method. As the first wire pads 13 are installed in the first region A1 of the first substrate 10, the end of the wire 300 may be protected by the underfill 400, preventing the end of the wire 300 from peeling off from the first wire pads 13. Therefore, a semiconductor package 1 with improved reliability can be provided.

The first or second semiconductor chip 100 or 200 may include, for example, a group IV semiconductor such as silicon (Si) and germanium (Ge), a group IV-IV compound semiconductor such as silicon-germanium (SiGe) and silicon carbide (SiC), or a group III-V compound semiconductor such as gallium arsenide (GaAs), indium arsenide (InAs), and indium phosphide (InP). The first or second semiconductor chip 100 or 200 may include a conductive region, such as a well doped with impurities. The first or second semiconductor chip 100 or 200 may have various device isolation structures such as shallow trench isolation (STI) structures.

The first or second semiconductor chip 100 or 200 may include a semiconductor device that includes a plurality of individual devices of various types. These individual devices may include various microelectronic devices such as metal-oxide-semiconductor field-effect transistors (MOSFETs), for example, complementary metal-oxide-semiconductor (CMOS) transistors, system large-scale integration (LSI) circuits, image sensors such as CMOS imaging sensors (CIS), micro-electro-mechanical systems (MEMS), active devices, and passive devices. The plurality of individual devices may be electrically connected to the conductive region of the first or second semiconductor chip 100 or 200. The semiconductor device may further include at least two of the plurality of individual devices, or conductive wiring or conductive plugs that electrically connect the plurality of individual devices to the conductive region of the first or second semiconductor chip 100 or 200. Additionally, the plurality of individual devices may be electrically isolated from other neighboring individual devices by an insulating film.

The second substrate 20 may be disposed above the first and second semiconductor chips 100 and 200. The second substrate 20 may be spaced apart from the first and second semiconductor chips 100 and 200 in a third direction Z (or a vertical direction). In some embodiments, the horizontal length and horizontal area of the second substrate 20 may be the same as the horizontal length and horizontal area of the first substrate 10. In some embodiments, the third direction Z may be perpendicular to the upper surface of the first substrate 10.

The second substrate 20 may include a plurality of second pads 25 and 27. The second pads 25 and 27 may include second upper pads 27 and second lower pads 25. The second substrate 20 and the second pads 25 and 27 are generally similar to the first substrate 10 and first pads 11 and 17, and thus will hereinafter be described, focusing mainly on the differences.

In some embodiments, the second substrate 20 may be a printed circuit board. For example, the second substrate 20 may be a multi-layer printed circuit board. In some embodiments, the second substrate 20 may be a redistribution structure including redistribution lines, redistribution vias, and a redistribution insulation layer that surrounds both the redistribution lines and the redistribution vias.

In some embodiments, the second substrate 20 may be an interposer substrate. In this case, the second substrate 20 may include a base layer and a wiring structure.

In some embodiments, the second substrate 20 may further include a second solder resist layer 22 and 24. The second solder resist layer 22 and 24 may include a second upper solder resist layer 24, which exposes the second upper pads 27 and covers the upper surface of the second substrate 20, and a second lower solder resist layer 22, which exposes the second lower pads 25 and covers the lower surface of the second substrate 20.

In some embodiments, the second substrate 20 may include a cavity 21, which is installed on a lower surface facing the first substrate 10. The lower surface at which the cavity 21 is formed may be adjacent to the upper surface of the first substrate 10. The cavity 21 may overlap an uppermost part of the wire 300 in a first direction X which is parallel to the upper surface of the first substrate 10. The cavity 21 may overlap the uppermost part of the wire in the third direction Z.

Accordingly, the space between the uppermost part of the wire 300 and the second substrate 20 can be secured, preventing damage to the wire 300 and allowing for a reduced size of the semiconductor package 1. For example, the cavity 21 may provide a space accommodating the uppermost part of the wire 300, thereby enabling a more compact semiconductor package 1 without causing damage to the wire 300. In some embodiments, the region where the cavity 21 is formed may overlap the uppermost part of the wire 300 in the third direction Z. In some embodiments, the uppermost part of the wire 300 may be inserted into the cavity 21, thereby overlapping the cavity 21 in the first and third directions X and Z. In some embodiments, the uppermost part of the wire 300 may be adjacent to a region where the cavity 21 is formed without being inserted into the cavity 21.

The mold layer 700 may fill the space between the first and second substrates 10 and 20, and may surround the first and second semiconductor chips 100 and 200. The mold layer 700 may cover the upper surface of the first substrate 10, the lower surface of the second substrate 20, and the underfill 400. Additionally, the mold layer 700 may fill the space between the lower surface of the second substrate 20 and the upper surfaces of the first and second semiconductor chips 100 and 200, ensuring that the first and second semiconductor chips 100 and 200 are spaced apart from the second substrate 20. The mold layer 700 may be, for example, an epoxy molding compound (EMC), but the present disclosure is not limited thereto.

In some embodiments, the first substrate 10 may include a plurality of vertical connectors 500 and 600, and the vertical connectors 500 and 600 may include a solder balls 600 and a plurality of core structures 500. The plurality of core structures 500 may be disposed inward of the plurality of solder balls 600 on the first substrate 10. In some embodiments, the plurality of solder balls 600 may be arranged along the perimeter of the first substrate 10, and the plurality of core structures 500 may be arranged in a region surrounded by the plurality of solder balls 600. For example, the plurality of core structures 500 may be arranged along a region where the plurality of solder balls 600 are arranged. In some embodiments, a region where the plurality of core structures 500 are arranged may be closer to the first semiconductor chip 100 than the region where the plurality of solder balls 600 are arranged.

The solder balls 600 may connect the first upper pads 11 to the second lower pads 25. In this case, the upper surfaces of the solder balls 600 may contact the second lower pads 25, and the lower surfaces of the solder balls 600 may contact the first upper pads 11. The solder balls 600 may have a rugby ball shape, with a vertical height greater than the horizontal width. The solder balls 600 may be formed of conductive solder. For example, the solder balls 600 may include at least one of tin (Sn), silver (Ag), and Cu.

The core structures 500 may be interposed between the first and second substrates 10 and 20. In some embodiments, some of the core structures 500 may connect the first upper pads 11 to the second lower pads 25. That is, the upper surfaces and lower surfaces of some of the core structures 500 may contact the second lower pads 25 and the first upper pads 11, respectively, while the upper surfaces and lower surfaces of other core structures 500 may not contact the second lower pads 25 and the first upper pads 11. In some embodiments, each of the core structures 500 may include a core layer 510 and a solder layer 530, which surrounds the core layer 510. In this case, the solder layer 530 of some of the core structures 500, which connect the first upper pads 11 to the second lower pads 25, may contact the second lower pads 25 and the first upper pads 11. In some embodiments, the core layer 510 may include Cu, but the present disclosure is not limited thereto. In some embodiments, the solder layer 530 may be formed of conductive solder. For example, the solder layer 530 may include at least one of Sn, Ag, and Cu, but the present disclosure is not limited thereto.

In some embodiments, each of the core structures 500 may have a rugby ball shape with a maximum horizontal width longer than a vertical height. In this case, the core layer 510 may have a rugby ball shape with a maximum horizontal width longer than a vertical height, and the solder layer 530 may surround the core layer 510, resulting in the core structures 500 having a rugby ball shape with the maximum horizontal width greater than the vertical height. However, the present disclosure is not limited to this. For example, the core layer 510 may have a spherical shape with equal horizontal width and vertical height, and the solder layer 530 may surround the core layer 510, resulting in each of the core structures 500 having a rugby ball shape with a horizontal width greater than the vertical height. In some embodiments, each of the core structures 500 may have a spherical shape with equal horizontal width and vertical height. In some embodiments, each of the core structures 500 may have a vertical height greater than the maximum horizontal width. In each of the core structures 500, the core layer 510 may have the shape similar to the shape of the corresponding core structure, thereby having a vertical height greater than the maximum horizontal width.

In some embodiments, the vertical height of each of the core structures 500 may be equal to the vertical height of each of the plurality of solder balls 600, and the maximum horizontal width of each of the core structures 500 may be greater than the maximum horizontal width of each of the solder balls 600. However, the present disclosure is not limited to this. The sizes of the core structures 500 and the solder balls 600 may be the same.

The core structures 500 which are interposed between the first and second substrates 10 and 20 may maintain the spacing between the first and second substrates 10 and 20, thereby preventing the bending of the semiconductor package 1 and improving the structural reliability of the semiconductor package 1.

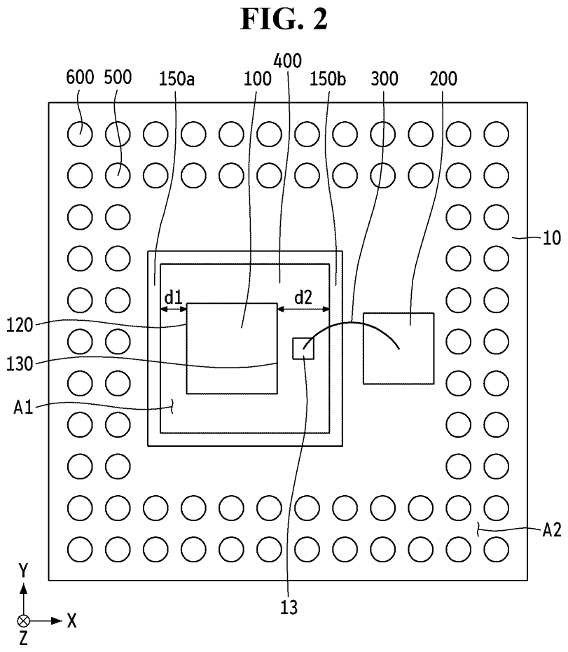

FIG. 2 is a top view of a semiconductor package according to some embodiments of the present disclosure. For convenience of explanation, the second substrate 20 is omitted.

Referring to FIG. 2, a semiconductor package 1 includes a first substrate 10, a first semiconductor chip 100, which is disposed on the first substrate 10, a second semiconductor chip 200, and a plurality of vertical connectors 500 and 600.

The first substrate 10 may include a plurality of first substrate pads. The first substrate pads may include a plurality of first upper pads 11 and a first wire pad 13, which are disposed on the upper surface of the first substrate 10. Through the first wire pad 13, the second semiconductor chip 200, mounted in a second region A2, may be electrically connected to the first substrate 10.

In some embodiments, the first substrate 10 may include an underfill dam 150, which protrudes from the upper surface of the first substrate 10. The underfill dam 150 may separate a first region A1 and the second region A2 of the first substrate 10. The underfill dam 150 may limit the area where underfill 400 is applied.

The first substrate 10 may include a plurality of first substrate pads. The first substrate pads may include the first upper pads 11 and the first wire pad 13, which are disposed on the upper surface of the first substrate 10. Through the first wire pad 13, the second semiconductor chip 200, mounted in the second region A2, may be electrically connected to the first substrate 10. For example, the second semiconductor chip 200 may be physically disposed in the second region A2, but electrically connected to the first substrate 10 via the first wire pad 13 disposed in the first region A1.

In some embodiments, the underfill dam 150 may include a first sub-dam 150a and a second sub-dam 150b. The second sub-dam 150b may be disposed between the first and second semiconductor chips 100 and 200. The distance between the first sub-dam 150a and the first semiconductor chip 100 may be a first distance d1. The distance between the second sub-dam 150b and the first semiconductor chip 100 may be a second distance d2. For example, the underfill dam 150 may surround the first semiconductor chip 100 and the first wire pad 13. The first semiconductor chip 100 and the first wire pad 13 may be disposed in a region surrounded by the underfill dam 150, and the second semiconductor chip 200 may be disposed outside the region surrounded by the underfill dam 150.

As the first wire pad 13 is disposed between the first semiconductor chip 100 and the second sub-dam 150b, the distance between the first sub-dam 150a and the first semiconductor chip 100 may be smaller than the distance between the second sub-dam 150b and the first semiconductor chip 100. That is, the first distance d1 may be smaller than the second distance d2.

In some embodiments, the first semiconductor chip 100 may be mounted in the first region A1 of the first substrate 10.

In some embodiments, the second semiconductor chip 200 may be mounted in the second region A2 of the first substrate 10. The second semiconductor chip 200 may be electrically connected to the first wire pad 13, installed on the first substrate 10, by a wire 300. Consequently, the second semiconductor chip 200 and the first substrate 10 may be electrically connected.

In some embodiments, the first wire pad 13, contacting the wire 300, may be installed in the first region A1 of the first substrate 10.

In some embodiments, the underfill 400 may be interposed between the first semiconductor chip 100 and the upper surface of the first substrate 10. The underfill 400 may surround a plurality of chip connection members 110 and the end of the wire 300 that contacts the first wire pad 13.

As the first wire pad 13 is installed in the first region A1 of the first substrate 10, the end of the wire 300 may be protected by the underfill 400 which prevents the end of the wire 300 from peeling off from the first wire pad 13. Therefore, a semiconductor package 1 with improved reliability can be provided.

In some embodiments, the first substrate 10 may include the vertical connectors 500 and 600, and the vertical connectors 500 and 600 may include a plurality of solder balls 600 and a plurality of core structures 500. The plurality of core structures 500 may be disposed inward of the plurality of solder balls 600 on the first substrate 10. In some embodiments, the plurality of solder balls 600 may be arranged along an edge of the first substrate 10, and the plurality of core structures 500 may be arranged in a region surrounded by the plurality of solder balls 600. For example, the plurality of core structures 500 may be arranged along a region where the plurality of solder balls 600 are arranged. In some embodiments, a region where the plurality of core structures 500 are arranged may be closer to the first semiconductor chip 100 than the region where the plurality of solder balls 600 are arranged.

The solder balls 600 may include at least one of Sn, Ag, and Cu, but the present disclosure is not limited thereto.

Each of the core structures 500 may include a core layer 510 and a solder layer 530, which surrounds the core layer 510.

In some embodiments, the core layer 510 may include Cu, but the present disclosure is not limited thereto. In some embodiments, the solder layer 530 may be formed of conductive solder. For example, the solder layer 530 may include at least one of Sn, Ag, and Cu, but the present disclosure is not limited thereto.

The solder balls 600 and the core structures 500 may be spaced apart from the first and second semiconductor chips 100 and 200, and may be arranged in columns along the edges of the first substrate 10, adjacent to the circumferences of the first and second semiconductor chips 100 and 200. The solder balls 600 and the core structures 500 may be spaced apart from one another.

In some embodiments, the solder balls 600 may be disposed outward of the core structures 500 along the four edges of the first substrate 10, but the present disclosure is not limited thereto. For example, the solder balls 600 may be arranged along the four edges of the first substrate 10, and the core structures 500 may be disposed in a region surrounded by the solder balls 600. In some embodiments, the core structures 500 may be disposed outward of the solder balls 600 along the four edges of the first substrate 10. For example, the core structures 500 may be arranged along the four edges of the first substrate 10, and the core structures 500 may be disposed in a region surrounded by the solder balls 600.

The core structures 500 which are disposed along the edges of the first substrate 10 may prevent the bending of the semiconductor package 1, thereby improving the structural reliability of the semiconductor package 1.

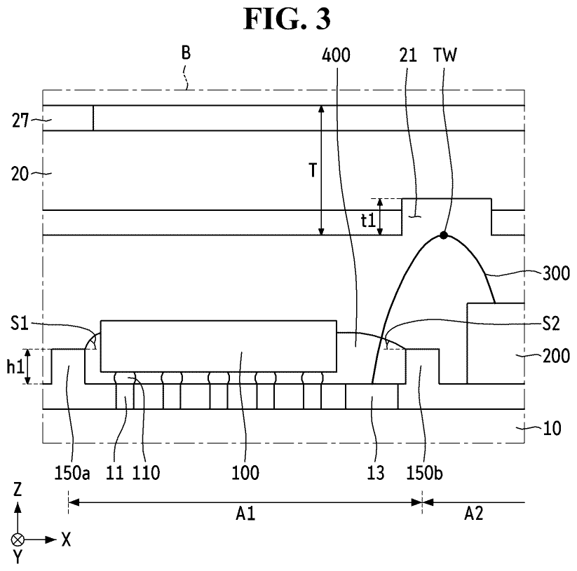

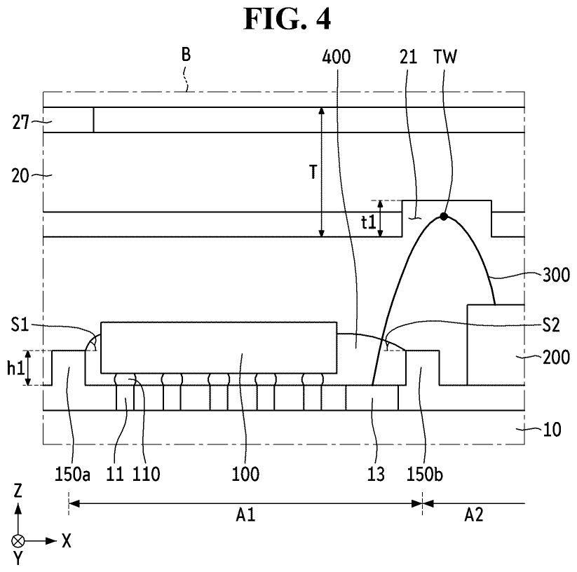

FIGS. 3 and 4 are cross-sectional views of part B of FIG. 1. For convenience of explanation, redundant descriptions of components identical to those in FIG. 1 will be omitted, and the embodiments of FIGS. 3 and 4 will be described, focusing mainly on the differences from the embodiment of FIG. 1.

Referring to FIG. 3, a first substrate 10 may include an underfill dam 150, which separates a first region A1 and a second region A2 of the first substrate 10. The underfill dam 150 may protrude from the upper surface of the first substrate 10, limiting the area where underfill 400 is applied. The height of the underfill dam 150 may be a first height h1. The first height h1 may be a value in range between 10 μm and 18 μm. In some embodiments, an upper surface of the underfill dam 150 may be lower than an upper surface of a first semiconductor chip 100.

In some embodiments, the underfill dam 150 may include a first sub-dam 150a and a second sub-dam 150b. The second sub-dam 150b may be disposed between the first semiconductor chip 100 and a second semiconductor chip 200.

The first substrate 10 may include a plurality of first substrate pads in the first region A1. The first substrate pads may include a plurality of first upper pads 11 and a first wire pad 13, which are disposed on the upper surface of the first substrate 10. Through the first wire pad 13, the second semiconductor chip 200, mounted in the second region A2, may be electrically connected to the first substrate 10.

As the first wire pad 13 is disposed between the first semiconductor chip 100 and the second sub-dam 150b, the distance between the first sub-dam 150a and the first semiconductor chip 100 may be smaller than the distance between the second sub-dam 150b and the first semiconductor chip 100.

In some embodiments, the underfill 400 may be interposed between the first semiconductor chip 100 and the upper surface of the first substrate 10. The underfill 400 may surround a plurality of chip connection members 110 and the end of a wire 300 that contacts the first wire pad 13.

The distance between the first sub-dam 150a and the first semiconductor chip 100 may be smaller than the distance between the second sub-dam 150b and the first semiconductor chip 100. Accordingly, the inclination angle of the underfill 400 between the first sub-dam 150a and the first semiconductor chip 100 may be greater than the inclination angle of the underfill 400 between the second sub-dam 150b and the first semiconductor chip 100. For example, the inclination angle of the underfill 400, applied between the first sub-dam 150a and the first semiconductor chip 100, may be a first angle S1. The inclination angle of the underfill 400, applied between the second sub-dam 150b and the first semiconductor chip 100, may be a second angle S2. The first angle S1 may be greater than the second angle S2. For example, the first angle S1 may correspond to the tangent of an upper surface of the underfill 400 at the point where the upper surface of the underfill 400 meets the first sub-dam 150a. The second angle S2 may correspond to the tangent of an upper surface of the underfill 400 at the point where the upper surface of the underfill 400 meets the second sub-dam 150b.

In some embodiments, a second substrate 20 may include a cavity 21, which is installed on the surface of the second substrate 20 that faces the first substrate 10. The thickness of the cavity 21 may be a first thickness t1. The thickness of the second substrate 20 may be a second thickness T. The ratio of the first thickness t1 to the second thickness T may be a value in a range between 1:8 and 1:10.

The cavity 21 may overlap an uppermost part TW of the wire 300 in the first direction X. For example, the uppermost part TW of the wire 300 may be inserted into the cavity 21. Accordingly, the space between the uppermost part TW of the wire 300 and the second substrate 20 can be secured, preventing damage to the wire 300 and allowing for a reduced size of the semiconductor package 1. For example, the cavity 21 may provide a space accommodating the uppermost part TW of the wire 300, thereby enabling a more compact semiconductor package 1 without causing damage to the wire 300. In some embodiments, the region where the cavity 21 is formed may overlap the uppermost part of the wire 300 in the third direction Z. In some embodiments, the uppermost part of the wire 300 may be inserted into the cavity 21, thereby overlapping the cavity 21 in the first and third directions X and Z. In some embodiments, the uppermost part of the wire 300 may be adjacent to a region where the cavity 21 is formed without being inserted into the cavity 21.

Referring to FIG. 4, in some embodiments, a first substrate 10 may include an underfill dam 150, which separates a first region A1 and a second region A2 of the first substrate 10. An underfill dam 150 may protrude from the upper surface of the first substrate 10, limiting the area where underfill 400 is applied. The height of the underfill dam 150 may be a first height h1. The first height h1 may be a value in a range between 10 μm and 18 μm.

In some embodiments, the underfill dam 150 may include a first sub-dam 150a and a second sub-dam 150b. The second sub-dam 150b may be disposed between a first semiconductor chip 100 and a second semiconductor chip 200. The distance between the first sub-dam 150a and the first semiconductor chip 100 may be a first distance. The distance between the second sub-dam 150b and the first semiconductor chip 100 may a second distance greater than the first distance.

The first substrate 10 may include a plurality of first substrate pads in the first region A1. The first substrate pads may include a plurality of first upper pads 11 and a first wire pad 13, which are disposed on the upper surface of the first substrate 10. Through the first wire pad 13, the second semiconductor chip 200, mounted in the second region A2, may be electrically connected to the first substrate 10.

As the first wire pad 13 is disposed between the first semiconductor chip 100 and the second sub-dam 150b, the distance between the first sub-dam 150a and the first semiconductor chip 100 may be smaller than the distance between the second sub-dam 150b and the first semiconductor chip 100.

In some embodiments, the underfill 400 may be interposed between the first semiconductor chip 100 and the upper surface of the first substrate 10. The underfill 400 may surround a plurality of chip connection members 110 and the end of a wire 300 that contacts the first wire pad 13.

The distance between the first sub-dam 150a and the first semiconductor chip 100 may be smaller than the distance between the second sub-dam 150b and the first semiconductor chip 100. Accordingly, the inclination angle of the underfill 400 between the first sub-dam 150a and the first semiconductor chip 100 may be greater than the inclination angle of the underfill 400 between the second sub-dam 150b and the first semiconductor chip 100. For example, the inclination angle of the underfill 400 applied between the first sub-dam 150a and the first semiconductor chip 100 may be a first angle S1, and the inclination angle of the underfill 400 applied between the second sub-dam 150b and the first semiconductor chip 100 may be a second angle S2. The first angle S1 may be greater than the second angle S2.

In some embodiments, a second substrate 20 may include a cavity 21, which is installed on the surface of the second substrate 20 that faces the first substrate 10. The thickness of the cavity 21 may be a first thickness t1. The thickness of the second substrate 20 may be a second thickness T. The ratio of the first thickness t1 to the second thickness T may be a value in a range between 1:8 and 1:10.

The cavity 21 may overlap an uppermost part TW of the wire 300 in a first direction X. Additionally, the uppermost part TW of the wire 300 may be disposed within the cavity 21. For example, the uppermost part TW of the wire 300 may be inserted into the cavity 21. Accordingly, the space between the uppermost part TW of the wire 300 and the second substrate 20 can be secured, preventing damage to the wire 300 and allowing for a reduced size of the semiconductor package 1.

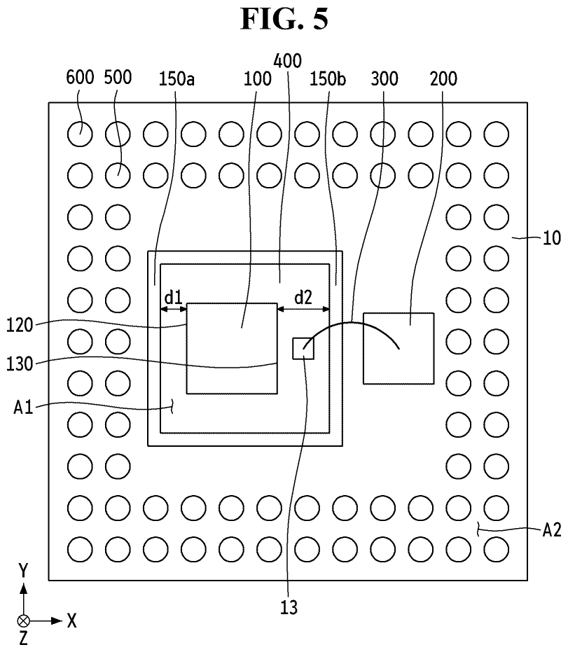

FIG. 5 is a top view of a semiconductor package according to some embodiments of the present disclosure. Referring to FIG. 5, a semiconductor package 1 includes a first substrate 10 and a first semiconductor chip 100, a second semiconductor chip 200, a third semiconductor chip 900, and a plurality of vertical connectors 500 and 600, which are disposed on the first substrate 10.

The first substrate 10 may include a plurality of first substrate pads. The first substrate pads may include a plurality of first upper pads 11, a first wire pad 13, and a second wire pad 16, which are disposed on the upper surface of the first substrate 10. Through the first and second wire pads 13 and 16, the second and third semiconductor chips 200 and 900, mounted in a second region A2, may be electrically connected to the first substrate 10.

In some embodiments, the first substrate 10 may include an underfill dam 150, which protrudes from the upper surface of the first substrate 10. The underfill dam 150 may separate a first region A1 and the second region A2 of the first substrate 10. The underfill dam 150 may limit the area where underfill 400 is applied. For example, the underfill dam 150 may surround the first semiconductor chip 100, the first wire pad 13, and the second wire pad 16. The second and third semiconductor chips 200 and 900 may be outside the region surrounded by the underfill dam 150.

In some embodiments, the underfill dam 150 may include a first sub-dam 150a and a second sub-dam 150b. The second sub-dam 150b may be disposed between the first semiconductor chip 100 and the second and third semiconductor chips 200 and 900. The distance between the first sub-dam 150a and the first semiconductor chip 100 may be a first distance d1. The distance between the second sub-dam 150b and the first semiconductor chip 100 may be a second distance d2.

As the first and second wire pads 13 and 16 are disposed between the first semiconductor chip 100 and the second sub-dam 150b, the first distance d1 between the first sub-dam 150a and the first semiconductor chip 100 may be smaller than the second distance d2 between the second sub-dam 150b and the first semiconductor chip 100. That is, the first distance d1 may be smaller than the second distance d2.

In some embodiments, the first semiconductor chip 100 may be mounted in the first region A1 of the first substrate 10.

In some embodiments, the second and third semiconductor chips 200 and 900 may be mounted in the second region A2 of the first substrate 10. The second and third semiconductor chips 200 and 900 may be electrically connected to the first and second wire pads 13 and 16, respectively, on the first substrate 10, by first and second wires 300 and 800, respectively. Consequently, the second and third semiconductor chips 200 and 900 and the first substrate 10 may be electrically connected. For example, the second and third semiconductor chips 200 and 900 may be disposed in the second region A2, but may be electrically connected to the first substrate 10 via the first and second wire pads 13 and 16 disposed in the first region A1.

In some embodiments, the first and second wire pads 13 and 16, contacting the first and second wires 300 and 800, respectively, may be installed in the first region A1 of the first substrate 10. In some embodiments, the second wire 800 may have a configuration similar to that of the first wire 300. For example, the uppermost end of second wire 800 may overlap a second cavity formed at the lower surface of the second substrate 200 in the third direction Z. The second cavity may have a configuration similar to that of the cavity 21 as shown in FIGS. 3 and 4.

In some embodiments, the underfill 400 may be interposed between the first semiconductor chip 100 and the upper surface of the first substrate 10. The underfill 400 may surround a plurality of chip connection members 110, the end of the first wire 300 that contacts the first wire pad 13, and the end of the second wire 800 that contacts the second wire pad 16.

As the first and second wire pads 13 and 16 are installed in the first region A1 of the first substrate 10, the ends of the first and second wires 300 and 800 are protected by the underfill 400, preventing the ends of the first and second wires 300 and 800 from peeling off from the first and second wire pads 13 and 16. Accordingly, a semiconductor package 1 with improved reliability can be provided.

In some embodiments, the first substrate 10 may include the vertical connectors 500 and 600, and the vertical connectors 500 and 600 may include a plurality of solder balls 600 and a plurality of core structures 500. The plurality of core structures 500 may be disposed inward of the solder balls on the first substrate 10. In some embodiments, the plurality of solder balls 600 may be arranged along an edge of the first substrate 10, and the plurality of core structures 500 may be arranged in a region surrounded by the plurality of solder balls 600. For example, the plurality of core structures 500 may be arranged along a region where the plurality of solder balls 600 are arranged. In some embodiments, a region where the plurality of core structures 500 are arranged may be closer to the first semiconductor chip 100 than the region where the plurality of solder balls 600 are arranged.

The solder balls 600 may include at least one of Sn, Ag, and Cu.

Each of the core structures 500 may include a core layer 510 and a solder layer 530, which surrounds the core layer 510.

In some embodiments, the core layer 510 may include Cu, but the present disclosure is not limited thereto. In some embodiments, the solder layer 530 may be formed of conductive solder. For example, the solder layer 530 may include at least one of Sn, Ag, and Cu, but the present disclosure is not limited thereto.

The solder balls 600 and the core structures 500 may be spaced apart from the first and second semiconductor chips 100 and 200 and may be arranged in columns along the edges of the first substrate 10, adjacent to the circumferences of the first, second, and third semiconductor chips 100, 200, and 900. The solder balls 600 and the core structures 500 may be spaced apart from one another.

In some embodiments, the solder balls 600 may be disposed outward of the core structures 500 along the four edges of the first substrate 10, but the present disclosure is not limited thereto. For example, the solder balls 600 may be arranged along the four edges of the first substrate 10, and the core structures 500 may be arranged in a region surrounded by the solder balls 600. In some embodiments, the core structures 500 may be disposed outward of the solder balls 600 along the four edges of the first substrate 10. For example, the core structures 500 may be arranged along the four edges of the first substrate 10, and the solder balls 600 may be arranged in a region surrounded by the core structures 500.

As the core structures 500 are disposed along the edges of the first substrate 10, the bending of the semiconductor package 1 can be prevented, thus improving the structural reliability of the semiconductor package 1.

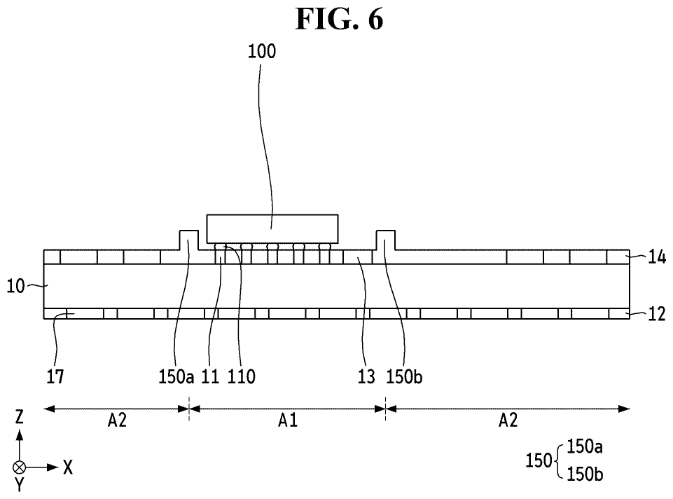

FIGS. 6 through 12 are cross-sectional views illustrating a method of fabricating a semiconductor package according to some embodiments of the present disclosure.

Referring to FIG. 6, a first semiconductor chip 100 is attached onto a first region A1 of a first substrate 10. For example, after attaching a plurality of chip connection members 110 to the first semiconductor chip 100, the chip connection members 110 may be attached to some of a plurality of first upper pads 11 of the first substrate 10, thereby attaching the first semiconductor chip 100 to the first substrate 10.

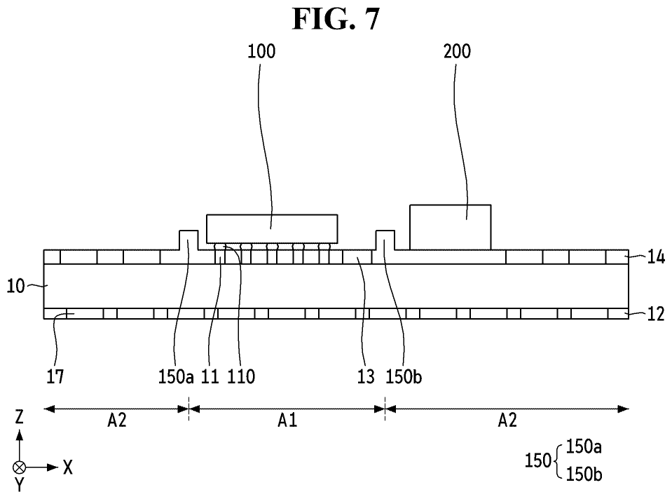

Referring to FIG. 7, a second semiconductor chip 200 is attached onto a second region A2 of the first substrate 10. For example, after applying an adhesive such as solder resist to the upper surface of the first substrate 10, the second semiconductor chip 200 may be attached to the second region A2 of the first substrate 10. No electrical connection between the second semiconductor chip 200 and the first substrate 10 is formed in the second region A2 thereof.

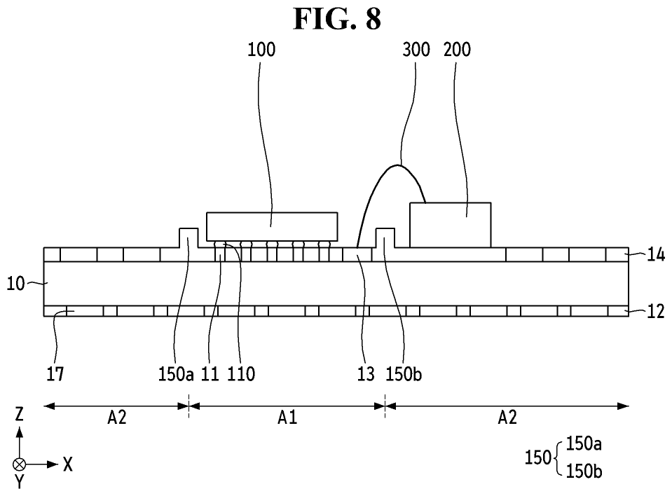

Referring to FIG. 8, the second semiconductor chip 200, disposed in the second region A2 of the first substrate 10, and a first wire pad 13, disposed in the first region A1 of the first substrate 10, are electrically connected by a wire 300.

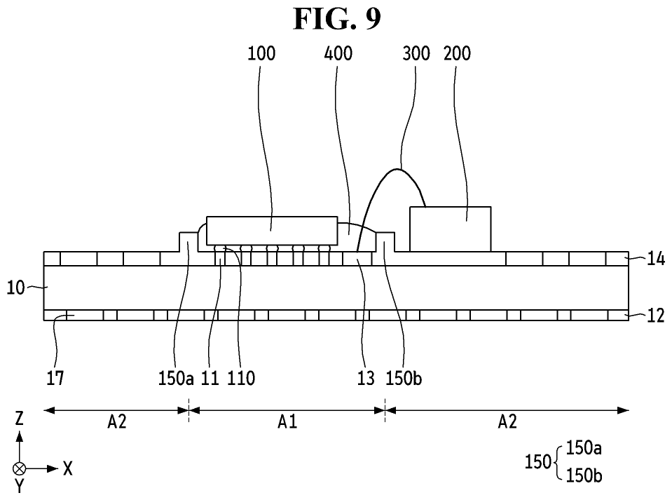

Referring to FIG. 9, the underfill 400 is formed inside an underfill dam 150. The underfill 400 may be formed, for example, by injecting a resin material into the underfill dam 150 using a capillary underfill method. The underfill 400 may fill the space between the first semiconductor chip 100 and the first substrate 10, and may be formed to surround the chip connection members 110 and the end of the wire 300 that contacts the first wire pad 13. As the first wire pad 13 is installed in the first region A1 of the first substrate 10, the end of the wire 300 is protected by the underfill 400, and the underfill 400 may prevent the end of the wire 300 from peeling off from the first wire pad 13. Accordingly, a semiconductor package 1 with improved reliability can be provided.

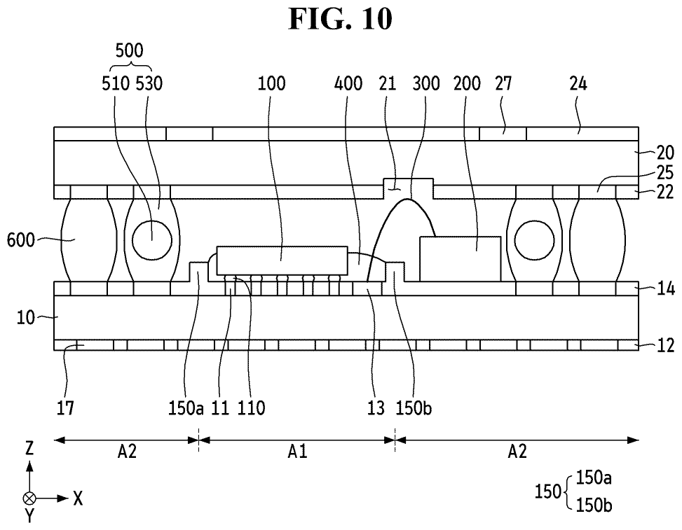

Referring to FIG. 10, a second substrate 20 may be disposed above the first and second semiconductor chips 100 and 200. The second substrate 20 may be spaced apart from the first and second semiconductor chips 100 and 200 in a third direction Z which is perpendicular to the upper surface of the first substrate 10. In some embodiments, the horizontal length and horizontal area of the second substrate 20 may be the same as the horizontal length and horizontal area of the first substrate 10.

In some embodiments, the second substrate 20 may be an interposer substrate. In this case, the second substrate 20 may include a base layer and a wiring structure.

In some embodiments, the second substrate 20 may include a cavity 21 (i.e., a first cavity), which is installed on the surface of the second substrate 20 that faces the first substrate 10. The cavity 21 may overlap the uppermost part of the wire 300 in a first direction X. In some embodiments, the uppermost part of the wire 300 may be inserted into the cavity 21. For example, the region where the cavity 21 is formed may overlap the uppermost part of wire 300 in the first and third directions X and Z. In some embodiments, the uppermost part of the wire 300 may be adjacent to the cavity 21 without being inserted thereinto.

Accordingly, the space between the uppermost part of the wire 300 and the second substrate 20 can be secured, preventing damage to the wire 300 and allowing for a reduced size of the semiconductor package 1.

Additionally, a plurality of core structures 500 and a plurality of solder balls 600 are formed between the first and second substrates 10 and 20.

The solder balls 600 may connect the first upper pads 11 and a plurality of second lower pads 25. In this case, the upper surfaces of the solder balls 600 may contact the second lower pads 25, and the lower surfaces of the solder balls 600 may contact the first upper pads 11. Each of the solder balls 600 may have a rugby ball shape with a vertical height greater than the horizontal width.

Some of the core structures 500 may connect the first upper pads 11 to the second lower pads 25. That is, the upper surfaces and lower surfaces of some of the core structures 500 may contact the second lower pads 25 and the first upper pads 11, respectively, while the upper surfaces and lower surfaces of other core structures 500 may not contact the second lower pads 25 and the first upper pads 11. In some embodiments, each of the core structures 500 may include a core layer 510 and a solder layer 530, which surrounds the core layer 510. In this case, the solder layer 530 of each of the core structures 500 that connect the first upper pads 11 and the second lower pads 25 may contact the second lower pads 25 and the first upper pads 11. In some embodiments, the core layer 510 may include Cu, but the present disclosure is not limited thereto. In some embodiments, the solder layer 530 may be formed of conductive solder. For example, the solder layer 530 may include at least one of Sn, Ag, and Cu, but the present disclosure is not limited thereto.

In some embodiments, the core structures 500 may have a rugby ball shape with a maximum horizontal width greater than a vertical height. In this case, the core layer 510 may have a rugby ball shape with a maximum horizontal width greater than a vertical height, and the solder layer 530 may surround the core layer 510, resulting in the core structures 500 having a rugby ball shape with the maximum horizontal width greater than the vertical height, but the present disclosure is not limited thereto. In some embodiments, the core layer 510 may have a spherical shape with equal horizontal width and vertical height, and the solder layer 530 may surround the core layer 510, resulting in the core structures 500 having a rugby ball shape with a maximum horizontal width greater than a vertical height. In some embodiments, the core structures 500 may have a spherical shape with equal horizontal width and vertical height. In some embodiments, each of the core structures 500 may have a vertical height greater than the maximum horizontal width. In each of the core structures 500, the core layer 510 may have the shape similar to the shape of the corresponding core structure, thereby having a vertical height greater than the maximum horizontal width.

The core structures 500 that are interposed between the first and second substrates 10 and 20 may maintain the distance between the first and second substrates 10 and 20, thereby preventing the bending of the semiconductor package 1 and improving the structural reliability of the semiconductor package 1.

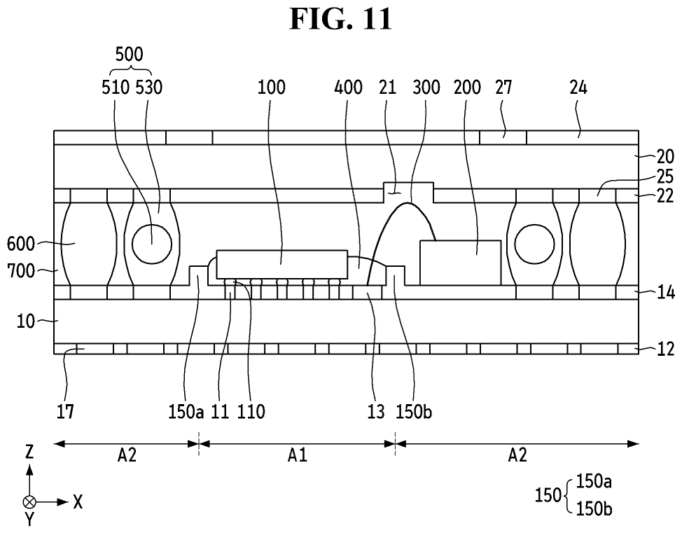

Referring to FIG. 11, a mold layer 700 is formed between the first and second substrates 10 and 20. The mold layer 700 may surround the first semiconductor chip 100, the second semiconductor chip 200, the solder balls 600, and the core structures 500.

For example, the mold layer 700 may be an EMC, but the present disclosure is not limited thereto.

During the formation of the mold layer 700, pressure may be applied between the first and second substrates 10 and 20.

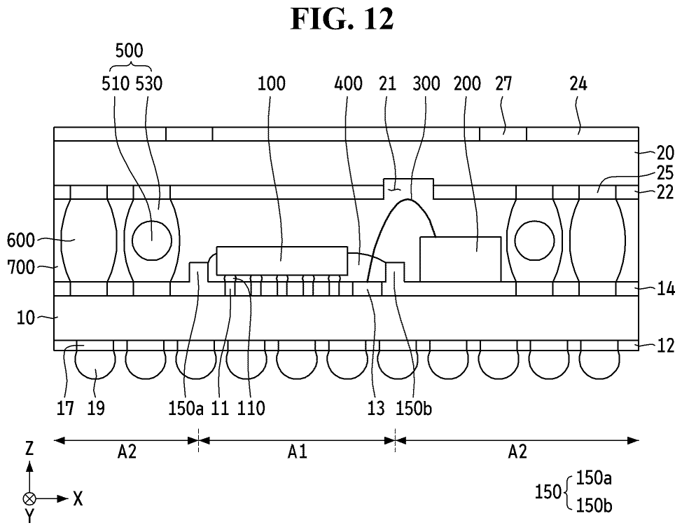

Referring to FIG. 12, a plurality of external connection terminals 19 may be attached to at least some of the first lower pads 17. In some embodiments, the external connection terminals 19 may be attached after attaching the first semiconductor chip 100, as described above with reference to FIG. 6.

The external connection terminals 19 may electrically connect the semiconductor package 1 to the outside. The external connection terminals 19 may be, for example, solder balls or bumps, but the present disclosure is not limited thereto.

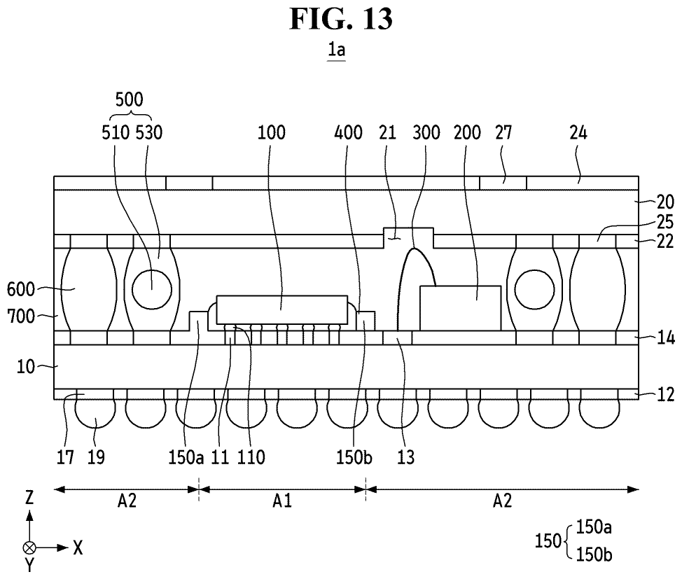

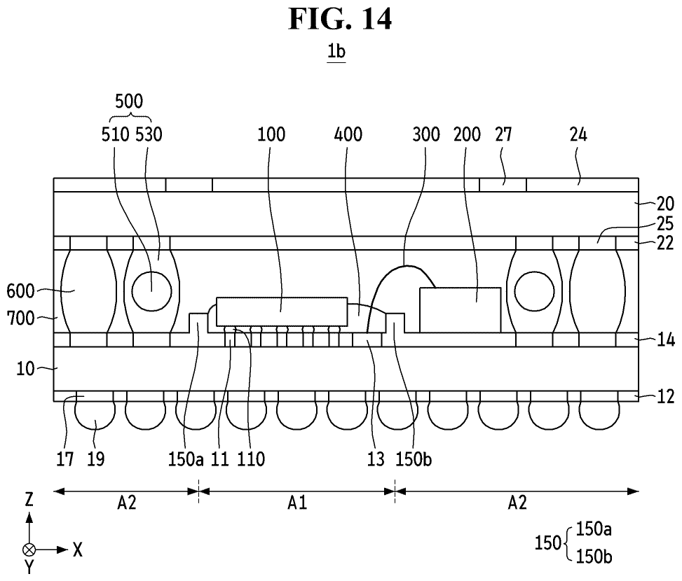

FIGS. 13 through 15 are cross-sectional views of semiconductor packages according to some embodiments of the present disclosure. The embodiments of FIGS. 13 and 14 are similar to the embodiment of FIG. 1, and thus will hereinafter be described, focusing mainly on the differences from the embodiment of FIG. 1.

Referring to FIG. 13, a semiconductor package 1 may include a first substrate 10 and a first semiconductor chip 100, a second semiconductor chip 200, a plurality of vertical connectors 500 and 600, and a second substrate 20, which are disposed on the first substrate 10.

A plurality of external connection terminals 19 may be attached to at least some of a plurality of first lower pads 17. The external connection terminals 19 may electrically connect the semiconductor package 1 to the outside. The external connection terminals 19 may be, for example, solder balls or bumps, but the present disclosure is not limited thereto.

In some embodiments, the first substrate 10 may include an underfill dam 150, which protrudes from the upper surface of the first substrate 10. The underfill dam 150 may separate a first region A1 and a second region A2 of the first substrate 10. The underfill dam 150 may limit the area where underfill 400 is applied.

The first substrate 10 may include a plurality of first substrate pads. The first substrate pads may include a plurality of first upper pads 11 and a first wire pad 13, which are disposed on the upper surface of the first substrate 10, and a plurality of first lower pads 17, which are disposed on the lower surface of the first substrate 10. Through the first wire pad 13, the second semiconductor chip 200 may be electrically connected to the first substrate 10.

In some embodiments, the underfill dam 150 may include a first sub-dam 150a and a second sub-dam 150b. The second sub-dam 150b may be disposed between the first and second semiconductor chips 100 and 200. The distance between the first sub-dam 150a and the first semiconductor chip 100 may be the same as the distance between the second sub-dam 150b and the first semiconductor chip 100.

In some embodiments, the first semiconductor chip 100 may be mounted in the first region A1 of the first substrate 10.

In some embodiments, a plurality of chip connection members 110 may be interposed between the first semiconductor chip 100 and some of the plurality of first upper pads 11 of the first substrate 10. The chip connection members 110 may be, for example, solder balls or bumps, but the present disclosure is not limited thereto. The first semiconductor chip 100 and the first substrate 10 may be electrically connected through the chip connection members 110.

In some embodiments, the second semiconductor chip 200 may be mounted in the second region A2 of the first substrate 10. The second semiconductor chip 200 may be electrically connected to the first wire pad 13, installed on the first substrate 10, by a wire 300. Consequently, the second semiconductor chip 200 and the first substrate 10 may be electrically connected.

In some embodiments, the first wire pad 13, contacting the wire 300, may be installed in the second region A2 of the first substrate 10.

The second substrate 20 may be disposed above the first and second semiconductor chips 100 and 200. The second substrate 20 may be spaced apart from the first and second semiconductor chips 100 and 200 in a vertical direction (or a third direction Z) which is perpendicular to the upper surface of the first substrate 10. In some embodiments, the horizontal length and horizontal area of the second substrate 20 may be the same as the horizontal length and horizontal area of the first substrate 10.

In some embodiments, the second substrate 20 may include a cavity 21, which is installed on the surface of the second substrate 20 that faces the first substrate 10. The cavity 21 may overlap the uppermost part of the wire 300 in a first direction X which is parallel to the upper surface of the first substrate 10. For example, the uppermost part of the wire 300 may be inserted into the cavity 21. The region where the cavity 21 is formed may overlap the uppermost part of the wire 300 in the third direction Z.

Accordingly, the space between the uppermost part of the wire 300 and the second substrate 20 can be secured, preventing damage to the wire 300 and allowing for a reduced size of the semiconductor package 1.

A mold layer 700 may fill the space between the first substrate 10 and the second substrate 20 and may surround the first and second semiconductor chips 100 and 200. The mold layer 700 may cover the upper surface of the first substrate 10, the lower surface of the second substrate 20, and the underfill 400. Additionally, the mold layer 700 may fill the space between the upper surfaces of the first and second semiconductor chips 100 and 200 and the lower surface of the second substrate 20 to keep the first and second semiconductor chips 100 and 200 apart from the second substrate 20. The mold layer 700 may be, for example, an EMC, but the present disclosure is not limited thereto.

In some embodiments, the first substrate 10 may include the vertical connectors 500 and 600, and the vertical connectors 500 and 600 may include a plurality of solder balls 600 and a plurality of core structures 500. The plurality of core structures 500 may be disposed inward of the solder balls on the first substrate 10. The first and second substrates 10 and 20 may be electrically connected through the solder balls 600 and the core structures 500. The core structures 500 which are interposed between the first and second substrates 10 and 20 may maintain the distance between the first and second substrates 10 and 20, thereby preventing the bending of the semiconductor package 1 and improving the structural reliability of the semiconductor package 1.

Referring to FIG. 14, a semiconductor package 1 may include a first substrate 10 and a first semiconductor chip 100, a second semiconductor chip 200, a plurality of vertical connectors 500 and 600, and a second substrate 20, which are disposed on the first substrate 10.

A plurality of external connection terminals 19 may be attached to at least some of a plurality of first lower pads 17. The external connection terminals 19 may electrically connect the semiconductor package 1 to the outside. The external connection terminals 19 may be, for example, solder balls or bumps, but the present disclosure is not limited thereto.

In some embodiments, the first substrate 10 may include an underfill dam 150, which protrudes from the upper surface of the first substrate 10. The underfill dam 150 may separate a first region A1 and a second region A2 of the first substrate 10. The underfill dam 150 may limit the area where underfill 400 is applied.

The first substrate 10 may include a plurality of first substrate pads. The first substrate pads may include a plurality of first upper pads 11 and a first wire pad 13, which are disposed on the upper surface of the first substrate 10, and a plurality of first lower pads 17, which are disposed on the lower surface of the first substrate 10. Through the first wire pad 13, the second semiconductor chip 200 may be electrically connected to the first substrate 10.

In some embodiments, the underfill dam 150 may include a first sub-dam 150a and a second sub-dam 150b. The second sub-dam 150b may be disposed between the first and second semiconductor chips 100 and 200.

As the first wire pad 13 is disposed between the first semiconductor chip 100 and the second sub-dam 150b, the distance between the first sub-dam 150a and the first semiconductor chip 100 may be smaller than the distance between the second sub-dam 150b and the first semiconductor chip 100.

In some embodiments, the first semiconductor chip 100 may be mounted in the first region A1 of the first substrate 10.

In some embodiments, a plurality of chip connection members 110 may be interposed between the first semiconductor chip 100 and some of the first upper pads 11 of the first substrate 10. The chip connection members 110 may be, for example, solder balls or bumps, but the present disclosure is not limited thereto. The first semiconductor chip 100 and the first substrate 10 may be electrically connected through the chip connection members 110.

In some embodiments, the second semiconductor chip 200 may be mounted in the second region A2 of the first substrate 10.

In some embodiments, the second semiconductor chip 200 may be electrically connected to the first wire pad 13, installed on the first substrate 10, by a wire 300. Consequently, the second semiconductor chip 200 and the first substrate 10 may be electrically connected.

In some embodiments, the first wire pad 13, contacting the wire 300, may be installed in the first region A1 of the first substrate 10.

In some embodiments, the underfill 400 may be interposed between the first semiconductor chip 100 and the upper surface of the first substrate 10. The underfill 400 may surround the chip connection members 110 and the end of the wire 300 that contacts the first wire pad 13. As the first wire pad 13 is installed in the first region A1 of the first substrate 10, the end of the wire 300 may be protected by the underfill 400, preventing the end of the wire 300 from peeling off from the first wire pad 13. Accordingly, a semiconductor package 1 with improved reliability may be provided.

The second substrate 20 may be disposed above the first and second semiconductor chips 100 and 200. The second substrate 20 may be spaced apart from the first and second semiconductor chips 100 and 200 in a third direction Z which is perpendicular to the upper surface of the first substrate 10. In some exemplary embodiments, the horizontal length and horizontal area of the second substrate 20 may be the same as the horizontal length and horizontal area of the first substrate 10.

A mold layer 700 may fill the space between the first and second substrates 10 and 20 and may surround the first and second semiconductor chips 100 and 200. The mold layer 700 may cover the upper surface of the first substrate 10, the lower surface of the second substrate 20, and the underfill 400. Additionally, the mold layer 700 may fill the space between the upper surfaces of the first and second semiconductor chips 100 and 200 and the lower surface of the second substrate 20 to keep the first and second semiconductor chips 100 and 200 apart from the second substrate 20.

In some embodiments, the first substrate 10 may include the vertical connectors 500 and 600, and the vertical connectors 500 and 600 may include a plurality of solder balls 600 and a plurality of core structures 500. The plurality of core structures 500 may be disposed inward of the solder balls 600 on the first substrate 10. The first and second substrates 10 and 20 may be electrically connected through the solder balls 600 and the core structures 500. The core structures 500 which are interposed between the first and second substrates 10 and 20 may maintain the distance between the first and second substrates 10 and 20, thereby preventing the bending of the semiconductor package 1 and improving the structural reliability of the semiconductor package 1.

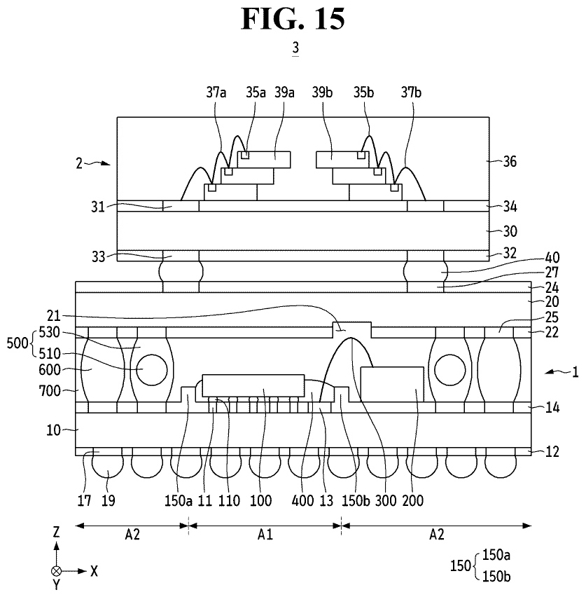

Referring to FIG. 15, a semiconductor package 3 may be a package-on-package type semiconductor package in which an upper package 2 is attached to a lower package 1.

The lower package 1 may be the same as the semiconductor package 1 of any one of FIGS. 1, 13, and 14, and thus, a detailed description thereof will be omitted.

The upper package 2 may include a third substrate 30, a plurality of semiconductor chip stacks 39a and 39b, which are disposed on the third substrate 30 and include first and second semiconductor chip stacks 39a and 39b, a second mold layer 36, which surrounds the first and second semiconductor chip stacks 39a and 39b, and a plurality of package connection pads 40, which are attached to the lower surface of the third substrate 30. The package connection pads 40 may be connected to a plurality of second upper pads 27.

The third substrate 30 may include a plurality of third pads. The third pads may include third upper pads 31, which are disposed on the upper surface of the third substrate 30, and third lower pads 33, which are disposed on the lower surface of the third substrate 30. The third pads may contain Cu. For example, the third pads may be formed of ED Cu foil, RA Cu foil, ultra-thin Cu foil, sputtered Cu, Cu alloy, etc.

The third upper pads 31 may electrically connect the semiconductor chip stacks (39a and 39b) to the third substrate 30. For example, the third upper pads 31 may be connected to semiconductor chip pads 35a and 35b of the semiconductor chip stacks 39a and 39b through third wires 37a and 37b.

Each of the semiconductor chip pads 35a and 35b may be disposed on the upper surface of the corresponding semiconductor chip. Each of the semiconductor chip pads 35a and 35b may be exposed on one side edge (e.g., the right edge or the left edge) of the upper surface of the corresponding semiconductor chip. A plurality of semiconductor chip pads 35a and 35b may be formed.

The semiconductor chip pads 35a and 35b may include, for example, at least one metal selected from Cu, aluminum (Al), tungsten (W), and titanium (Ti).

However, the present disclosure is not limited to this. In some embodiments, vias may be formed instead of the semiconductor chip pads 35a and 35b. In this case, the semiconductor chip stacks 39a and 39b and the third substrate 30 may be electrically connected through the vias.

In some embodiments, the third substrate 30 may further include a third solder resist layer 32 and 34, which covers the upper and lower surfaces of the third substrate 30. The third solder resist layer 32 and 34 may include a third upper solder resist layer 34, which exposes the third upper pads 31 and covers the upper surface of the third substrate 30, and a third lower solder resist layer 32, which exposes the third lower pads 33 and covers the lower surface of the third substrate 30.

A plurality of package connection pads 40 may be attached to the third lower pads 33. For example, the package connection pads 40 may be interposed between the second upper pads 27 and the third lower pads 33.

While exemplary embodiments of the present invention have been described above with reference to the accompanying drawings, the present invention is not limited to the above embodiments and may be embodied in various other forms. Those skilled in the art will understand that various modifications and changes can be made without departing from the spirit and essential characteristics of the present invention. Therefore, the above-described embodiments are intended to be illustrative and not restrictive in every respect.

What is claimed is:

1. A semiconductor package comprising:
a first substrate including a first region and a second region;
an underfill dam separating the first substrate into the first region and the second region, wherein the underfill dam surrounds the first region;
a first semiconductor chip mounted on the first region;
a second semiconductor chip mounted on the second region;
a first electrode pad and a second electrode pad disposed on the first region;
a bump connecting the first electrode pad to the first semiconductor chip;
a first wire connecting the second electrode pad to the second semiconductor chip; and
an underfill disposed on the first region and surrounding the bump and an end of the first wire that contacts the second electrode pad.

2. The semiconductor package of claim 1,
wherein the underfill dam includes a first sub-dam and a second sub-dam, which are disposed on opposite sides of the first semiconductor chip,
the second sub-dam is disposed between the first and second semiconductor chips, and
a distance between the first sub-dam and the first semiconductor chip is smaller than a distance between the second sub-dam and the first semiconductor chip.

3. The semiconductor package of claim 2,
wherein the underfill includes:
a first inclined surface formed between a first edge of the first semiconductor chip and the first sub-dam; and
a second inclined surface formed between a second edge, opposite to the first edge, of the first semiconductor chip and the second sub-dam, and
wherein an inclination angle of the first inclined surface is greater than an inclination angle of the second inclined surface.

4. The semiconductor package of claim 1,
wherein a height of the underfill dam has a value in a range between 10 μm and 18 μm.

5. The semiconductor package of claim 1, further comprising:
a second substrate disposed on the first substrate; and
a plurality of vertical connectors disposed between the first and second substrates and electrically connecting the first and second substrates with each other.

6. The semiconductor package of claim 5,
wherein the second substrate includes:
a lower surface adjacent to the first substrate; and
a cavity disposed at the lower surface of the second substrate, and
wherein the cavity overlaps an uppermost part of the first wire in a vertical direction perpendicular to an upper surface of the first substrate.

7. The semiconductor package of claim 6,
wherein the uppermost part of the first wire is inserted into the cavity.

8. The semiconductor package of claim 6,
wherein the second substrate has a first thickness,
the cavity has a second thickness, and
a ratio of the first thickness to the second thickness has a value in a range between 8:1 and 10:1.

9. The semiconductor package of claim 5,
wherein the plurality of vertical connectors further include a plurality of core structures and a plurality of solder balls,
each of the plurality of core structures includes a solder layer and a core layer,
the solder layer includes at least one of tin (Sn), silver (Ag), and copper (Cu), and
the core layer includes Cu.

10. The semiconductor package of claim 1,
wherein the first semiconductor chip is a modem chip, and
the second semiconductor chip is a memory chip.

11. The semiconductor package of claim 1, further comprising:
a second substrate disposed on the first substrate;
a third substrate disposed on the second substrate;
a third semiconductor chip mounted on the third substrate; and
a package connection pad disposed between the second and third substrates.

12. The semiconductor package of claim 1, further comprising:
a second substrate disposed on the first substrate;
a third semiconductor chip mounted outside the underfill dam;
a third electrode pad disposed on the first region surrounded by the underfill dam; and
a second wire electrically connecting the third electrode pad to the third semiconductor chip,
wherein the underfill surrounds a second end of the second wire that contacts the second electrode pad, and
the second substrate includes a second cavity overlapping an uppermost part of the second wire in a vertical direction perpendicular to an upper surface of the first substrate.

13. The semiconductor package of claim 1, further comprising:
a second substrate disposed on the first substrate; and
a mold layer disposed between the first and second substrates, and surrounding the first and second semiconductor chips.

14. A method of fabricating a semiconductor package, comprising:
providing a first substrate including a first region and a second region, which are separated by an underfill dam;
providing a first electrode pad and a second electrode pad on the first region;
mounting a first semiconductor chip on the first region, wherein the first semiconductor chip is connected to the first electrode pad;
mounting a second semiconductor chip on the second region;
connecting the second semiconductor chip to the second electrode pad with a wire; and
applying an underfill into the underfill dam after the connecting of the second semiconductor chip to the second electrode pad with the wire,
wherein the underfill surrounds an end of the wire that contacts the second electrode pad.

15. The method of claim 14, further comprising:
mounting a plurality of core structures and a plurality of solder balls on the first substrate;
disposing a second substrate on the first and second semiconductor chips; and
forming a cavity at a lower surface of the second substrate,
wherein the lower surface of the second substrate is adjacent to the first substrate,
the cavity overlaps an uppermost part of the wire in a vertical direction perpendicular to an upper surface of the first substrate,
each of the plurality of core structures includes a solder layer and a core layer,
the solder layer includes at least one of tin (Sn), silver (Ag), and copper (Cu),
the core layer includes copper, and
a region where the plurality of core structures are disposed is closer to the first semiconductor chip than a region where the plurality of solder balls are disposed.

16. The method of claim 15,
wherein the uppermost part of the wire is inserted into the cavity.

17. The method of claim 15, further comprising:
forming a mold layer between the first and second substrates; and
attaching the solder balls to a lower surface of the first substrate.

18. The method of claim 14,
wherein the underfill dam includes a first sub-dam and a second sub-dam, which are disposed on opposite sides of the first semiconductor chip,
the second sub-dam is disposed between the first semiconductor chip and the second semiconductor chip, and
a distance between the first sub-dam and the first semiconductor chip is smaller than a distance between the second sub-dam and the first semiconductor chip.

19. The method of claim 18,
wherein the underfill includes:
a first inclined surface formed between a first edge of the first semiconductor chip and the first sub-dam; and
a second inclined surface formed between a second edge of the first semiconductor chip and the second sub-dam, and
wherein an inclination angle of the first inclined surface is greater than an inclination angle of the second inclined surface.

20. A semiconductor package comprising:
a first substrate including a first region and a second region;
an underfill dam separating the first substrate into the first region and the second region, wherein the underfill dam surrounds the first region;
an interposer disposed on the first substrate;
a third substrate disposed on the interposer;
a first semiconductor chip mounted on the first region;
a second semiconductor chip mounted on the second region;
a third semiconductor chip mounted on the third substrate;
a first electrode pad and a second electrode pad disposed on the first region;
a package connection pad disposed between the interposer and the third substrate;
a bump connecting the first electrode pad to the first semiconductor chip;
a wire connecting the second electrode pad to the second semiconductor chip;
a plurality of vertical connectors disposed between the first substrate and the interposer, electrically connecting the first substrate to the interposer; and
an underfill disposed on the first region and surrounding the bump and an end of the wire that contacts the second electrode pad,
wherein the interposer includes:
a lower surface facing the first substrate; and
a cavity disposed at the lower surface of the interposer,
the cavity overlaps an uppermost part of the wire,
the plurality of vertical connectors include a plurality of core structures and a plurality of solder balls,
each of the plurality of core structures includes a solder layer and a core layer,
the solder layer includes at least one of tin (Sn), silver (Ag), and copper (Cu),
the core layer includes copper, and
a region where the plurality of core structures are disposed is closer to the first semiconductor chip than a region where the plurality of solder balls are disposed.
